(19) United States
(12) Patent Application Publication
(10) Pub. No.: US 2004/0168626 A1
(43) Pub. Date: Sep. 2, 2004

(54) Process for forming semiconductor quantum dots with superior structural and phological stability

(76) Inventors: Peter Moeck, Portland, OR (US); Nigel David Browning, San Francisco, CA (US)

Correspondence Address: Welsh & Katz, 22nd Floor, 120 South Riverside Plaza, Chicago, IL, 60606, US

(21) Appl. No.: 10/484,287

(22) PCT Filed: Jul. 19, 2002
(86) PCT No.: PCT/US02/22962

Related U.S. Application Data
(60) Provisional application No. 60/306,794, filed on Jul. 20, 2001.

(51) Int. Cl. C30B 23/00; C30B 25/00; C30B 28/12; C30B 28/14

(52) U.S. Cl. 117/84; 117/89

(57) ABSTRACT

A process for forming thermodynamically stable, epitaxially grown semiconductor quantum dots with varying degree of atomic long-range order is described. This procedure encompasses heteroepitaxial growth, external lattice mismatch strain and point defect engineering, and the conversion of a thermodynamically metastable semiconductor alloy predecessor structure into a structure of compositionally modulated/structurally transformed semiconductor quantum dots with varying degree of atomic long-range order by specific thermal treatments. These quantum dots are structurally stable at room temperature and reasonable device operation temperatures. The key structural transformation is achieved through thermodynamically driven atomic ordering. The resulting thermodynamically stable quantum dots have extensive applications in opto- and micro-electronic devices where the performance depends on both the structural and chemical homogeneity and long-term structural stability of these so called zero-dimensional entities.

### CROSS REFERENCE TO RELATED APPLICATIONS

This application claims the benefit of priority to U.S. Provisional Application No. 60/306,794 filed on Jul. 20, 2001.

### FEDERAL RESEARCH STATEMENT

This invention was made with government support under Grant No. DMR-9733895 awarded by the National Science Foundation. The U.S. government has certain rights in the invention.

### BACKGROUND OF THE INVENTION

1. Field of the Invention

The invention relates to the fields of fabrication processes and resulting structures of epitaxially grown semiconductor quantum dots and opto- and micro-electronic devices where the performance depends on these so called zero-dimensional entities.

2. Description of the Prior Art

Three conditions are generally accepted as defining a semiconductor quantum dot that is employable in semiconductor device applications (Ledentsov et al.): (1) sizes in three dimensions appropriate for quantum confinement effects, (2) a semiconductor agglomerate of a smaller band gap embedded in a semiconductor matrix of a larger band gap, and (3) essentially no one- (such as dislocations), two- (such as stacking faults), and three-dimensional defects (such as foreign phases). The substantially reduced band gap widths and the nanometer size of the quantum dots are frequently noted features of interest for the design of novel and improved opto- and microelectronics devices, e.g. (In,Ga)As quantum dot based semiconductor lasers that luminesce at the technically valuable 1.3 μm wavelength for silica fiber based optical communications (Ustinov et al.) or infrared inter-subband photoconductive detectors (Razeghi, Towe et al.). Devices that combine opto- and microelectronics are also possible on the basis of α-Sn or Sn rich quantum dots, which possess a direct band gap, in Si or Ge matrices (Ragan et al.).

For the first factor, the size of the quantum dots is typically on the order of tens of nanometers. If a suitable embedded agglomerate in a matrix is larger than a certain size, the behavior of the electrons and/or holes contained in this agglomerate can be described by classical rather than quantum mechanics and the system ceases to function as a quantum dot.

While the second factor can be determined in a first approximation by the chemical composition of the quantum dot, other factors such as the size and shape of the quantum dot, the regularity of the array of dots and the presence or absence of atomic long range order have also control over the properties of the quantum dots. In general, atomic long-range ordering (i.e. super cell formation) of varying degrees in semiconductor alloys is always accompanied by band gap reductions (Zunger at al., Lanks et al.) which are due to band gap folding followed by repulsion between the folded states (Wei et al.). The largest reductions of the band gap are expected to occur for cases of complete atomic long-range order. As a chemical superlattice can be considered as representing a case of partial long-range order, band gap reductions are expected for such structures as well (Lanks et al.), although to a lesser extent than for cases of complete long-range order. The defects mentioned in the third factor can serve to disrupt properties that would otherwise be present in the system.

Ordinarily strained semiconductor quantum dots are entities which are metastable semiconductor random alloy predecessor structures of the semiconductor quantum dots with superior long term structural stability (consisting of transformed structures/compositionally modulated with varying degree of atomic long-range order) that are the subject of the present invention. There is a very substantial body of patent and scientific literature on epitaxial growth and external lattice mismatch strain engineering (e.g. monographs by Jacak et al., Bimberg et al., Y. Masumoto and T. Takagahara (Editors), and Pearsall (Editor)).

This large body of patent and scientific literature teaches procedures that result in ordinarily strained quantum dots that are structurally unstable at room temperature (Möck et al., 2001a, 2002a) and at a reasonable device operation temperature. Structural instability can make these ordinarily strained semiconductor quantum dots unsuitable for use in applications that need long lasting performance or long-term consistent performance.

The few procedures which result in other types of epitaxially grown semiconductor quantum dots will be discussed in greater detail below after a brief introduction to ordinarily strained quantum dots (including random alloy (Sn,Si) quantum dots in Si matrix that grow by phase separation in the diamond structural prototype) and their structural metastability.

As far as forming quantum dots using heteroepitaxy is concerned, some technically important semiconductors are commonly classified in 4 groups: element semiconductors, e.g. Ge and Si; III-V compound semiconductors, e.g. InAs and GaAs; II-VI compound semiconductors, e.g. CdSe and ZnSe, IV-VI compound semiconductors, e.g. PbSe and PbTe. For thin heteroepitaxial films within each of these groups, there is usually a more or less complete solid solubility between the members of a particular group, leading to the formation of semiconductor alloys even if there are miscibility gaps for the same group members in the bulk crystal. The structural prototypes of each group, i.e. diamond, sphalerite, wurtzite, or sodium chloride, determine the structure of the semiconductor alloy. Ideally all of the atoms are distributed completely randomly over their respective sublattices, but in reality there is always some clustering and anticlustering, leading to a less than random arrangement of the atoms in the alloys which is also called short-range ordering (Mikkelson et al., Sher at al.). Regardless of this base-level atomic ordering without a periodic long-range correlation, we will consider throughout this text a semiconductor alloy as possessing a generally random distribution of the atoms in a structure that is derived from the structural prototype of the group to which the constituents of the alloy belong.

As a semiconductor quantum dot, an ordinarily strained quantum dots contains substantially more of the element or compound, that possesses the smaller band gap. (E.g. more Sn if the quantum dots consists of a (Sn,Si) alloy embedded in a matrix of Si), or of the binary compound (e.g. InAs if the quantum dot consists of a (In,Ga)As alloy embedded in a GaAs matrix; CdSe if the quantum dot consists of a (Cd,Zn)Se alloy embedded in a ZnSe matrix). Accordingly, ordinarily strained quantum dots and their surrounding matrix possess a significantly different chemical composition but the same structural prototype.

It is well known that alloying of the elements or compounds (e.g. the formation of (Sn,Si) alloys, Ragan et al.; (In,Ga)As alloys, Joyce et al.; and (Cd,Zn)Se alloys, Strassburg et al.) takes place during the various production processes of ordinarily strained quantum dots. Because this alloying is generally considered by those of ordinary skill in the art to be important for the Stranski-Krastanow growth mode (and its variants such as the deposition of strained layers in the CdSe/ZnSe system to thicknesses below the Stranski-Krastanow transition or to thicknesses below one complete monolayer) to operate in semiconductors (Walter et al.) and is resulting in a rather constant effective chemical composition of ordinarily strained quantum dots regardless of differences in the nominally deposited structures (Galluppi et al.), it is of little consequence if pure elements and compounds or alloys are deposited epitaxially. This alloying, among other factors, is also important for the formation of Sn rich substitutional solution quantum dots in Si as these entities are formed by means of phase separation (Ragan et al.).

Besides a substantially different band gap widths, ordinarily stained quantum dots and the matrix that surrounds them always have different lattice constants. The difference in the lattice constants is usually substantial. In the GaAs quantum dots in (Al,Ga)As matrix system and the (Hg,Cd)Te quantum dots in CdTe matrix system, on the other hand, the lattice mismatch is not substantial but nevertheless conceptually not negligible. If the quantum dot has the same structure prototype as the matrix, this difference in the lattice constant results in the quantum dot being under compression or tension stresses. These stresses lead to strains in quantum dots and it is these strains that the specifier “ordinarily strained” in this particular type of quantum dot refers to.

In the past, those of ordinary skill in the art have generally assumed that what are called here “ordinarily strained quantum dots” are structurally stable at room temperature and a reasonable device operation temperature. A number of devices have already been produced on the basis of ordinarily strained quantum dots, e.g. Ustinov et al. and Towe et al., but published knowledge of long term performance is lacking. This is because those of ordinary skill in the art generally believed that ordinarily strained semiconductor quantum dots are structurally stable at room temperature and any reasonable device operation temperature. Without this conviction, the scientific community is unlikely to have gone through all of the efforts of developing technologies for the production of novel and improved opto- and microelectronic devices on the basis of ordinarily strained semiconductor quantum dots since their discovery in 1985 (Goldstein at al.). There is, however, one medium term study on the device performance of (In,Ga)As/GaAs based quantum dot lasers (Liu et al.) and it was found that the live time of the devices could be enhanced to approximately 9000 hours (from approximately 1200 hours) if the ordinarily strained quantum dots were embedded in stain reducing (In,Ga)As cladding layers (rather than nominally pure GaAs cladding layers).

Not being truly thermodynamically stable but only metastable on a time scale of a few tens of months, the atomic arrangements of ordinarily strained quantum dots do change over time. With the thermodynamically driven change in the structure of ordinarily strained quantum dots, all of the structure dependent properties that made this type of semiconductor quantum dots useful in the first place for opto- and microelectronic devices do change as well. With respect to opto- and microelectronics devices, this structural change means in the most benign scenario simply a shift in their device performance over time that does not seriously deteriorate the overall device performance. In more serious scenarios, other types of devices that are based on ordinarily strained quantum dots are destined to fail over time.

As mentioned above, a minor side branch of current technology produces directly semiconductor quantum dots with transformed structures/internal compositional modulations of varying degrees of atomic long range order that may or may not be thermodynamically stable at room temperature. Representative works of prior art on this side branch are described below.

Mintairov et al. observed indirect evidence for the spontaneous formation of structurally transformed/compositionally modulated semiconductor quantum dots of partial long-range atomic order in epitaxial GaAs₁₋ₓSbₓ solid solutions grown by liquid phase epitaxy on GaAs substrates. These entities with ordered atomic arrangements are thought to have come into being by a decomposition of the GaAs₁₋ₓSbₓ alloy into phase separated InGaAs₂/GaAs structures. Although the outcome of this epitaxial growth process is similar to the final outcome of the application of the present invention, the fundamental difference is that there was no application of a specific thermal treatment below the critical temperature for atomic rearrangements of the metastable semiconductor alloy predecessor structure, no application of external lattice mismatch stain and point defect engineering, and no combination of these two means of controlling the formation rate of compositionally modulated/structurally transformed semiconductor quantum dots in Mintairov's and co-workers' study.

Other authors, e.g. Oelgart et al., have used different gas phase epitaxy techniques, that are more suited to produce metastable semiconductor alloy structures as they are operating far from thermodynamic equilibrium, for the growth of strained (In,Ga)(As,Sb) layers and observed indirect evidence for the spontaneous formation of compositionally modulated/structurally transformed quantum dots. As no specific thermal treatment below the critical temperature for atomic rearrangements, no external lattice mismatch strain and point defect engineering, and no combination of these two means of controlling the formation rate of structurally transformed/compositionally modulated semiconductor quantum dots has been employed in such studies, they do not differ conceptually from the method used by Mintairov et al. In addition, the formation of structurally transformed/compositionally modulated quantum dots in a strained or lattice matched epilayer grown by gas phase epitaxy is strongly dependent on kinetic surface effects such as atomic surface reconstructions and only weakly determined by the thermodynamics of the bulk of the epilayer (Zunger et al.). Such quantum dots are, thus, not necessarily in their thermodynamic ground state.

Zakharov et al., Werner et al., Cirlin et al. observed direct evidence for the spontaneous formation of atomically ordered nano-agglomerates (with a novel structure that may be a high temperature modification of InAsSi₂) in a solid solution of InAs and Si, i.e. a system that cannot be regarded as a typical semiconductor alloy since the constituents belong to different groups as they possess different structural prototypes and where the solid solubility is even in cases of heteroepitaxy severely limited. This new phase came into being as a result of interdiffusion of nm thin InAs and Si layers. It is not known if the observed entities with compositional modulation/structural transformation are thermodynamically stable at room temperature. The authors are furthermore not sure if these nano-agglomerates meet all of the criteria for an entity to be considered a semiconductor quantum dot, see above. As no specific thermal treatment below the critical temperature for atomic rearrangements of this metastable structure, no external lattice mismatch strain and point defect engineering effort, and no combination of these two means of controlling the formation rate of structurally transformed/compositionally modulated semiconductor quantum dots has been employed in these studies, Zakharov's, Werner's, Cirlin's and co-workers' method is for the above given reasons conceptually different to the present invention.

As far as prior arts of the fabrication of semiconductor devices is concerned, it is well known (e.g. Tan et al.) that self-diffusion of the constituent atoms in a semiconductor and interdiffusion of the constituent atoms of a semiconductor heterostructure are controlled by the presence of dopant and other point defects. There are also papers on the Fermi-level effect of dopant and/or other point defects on ordinarily strained quantum dots (Shchekin et al.) and on other semiconductor alloy predecessor structures (Deppe et al.). It is equally well known (e.g. monograph by Flynn) that mechanical stresses, such as the once which lead to the strained status of ordinarily strained quantum dots, are controlling the rate of atomic rearrangements by modifying diffusion processes.

The dependency of the rate of atomic rearrangements on the particulars of the mechanical stress fields opens up the opportunity of external lattice mismatch strain engineering, i.e. the deliberate creation of a kind of a particular stress field in and around ordinarily strained quantum dots by any means, e.g. depositing a sequence of semiconductor layers that possess in their bulk form a lattice constant that differs from that of the unstrained lattice constant of the quantum dots. There are also many different methods of incorporating dopants into a semiconductor and of producing point defects of various kinds. Combination of external lattice mismatch strain engineering and point defect engineering of any kind will also influence the rate of the structural transformation of ordinarily strained quantum dots. These transformations can desirably lead to the formation of more stable quantum dots, and quantum dots having varied degrees of atomic long-range order that can be the same as or different from the short- and long range order present in semiconductor quantum dots available through current technologies. Either or both of more stable quantum dots or more control over the degree and kind of atomic order is useful in fabricating useful quantum dot devices.

### SUMMARY OF THE INVENTION

The present invention relates to an improved method for forming compositionally modulated/structurally transformed semiconductor quantum dots that are structurally more stable and apparatus incorporating such compositionally modulated/structurally transformed semiconductor quantum dots.

One method comprises the steps of:

providing at least one metastable heteroepitaxially grown semiconductor alloy predecessor structure made of a first semiconductor material embedded in a matrix made of a second semiconductor material using a heteroepitaxial growth method, wherein the metastable heteroepitaxially grown semiconductor alloy predecessor structure has external lattice mismatch strain relative to the matrix material; and

heating the metastable heteroepitaxially grown semiconductor alloy predecessor structure embedded in the matrix material at a temperature below the critical temperature for atomic ordering of the first semiconductor material for a period of time;

wherein the metastable heteroepitaxially grown semiconductor alloy predecessor structure form compositionally modulated/structurally transformed semiconductor quantum dots that are more structurally stable than ordinarily strained quantum dots.

In accordance with another aspect of the invention, the compositionally modulated/structurally transformed semiconductor quantum dots are structurally stable at a reasonable device operation temperature.

In a preferred embodiment of the present invention, the compositionally modulated/structurally transformed semiconductor quantum dots are structurally stable at room temperature.

The method of the present invention also relates to a method comprising the steps of:

providing a plurality of metastable heteroepitaxially grown semiconductor alloy predecessor structures surrounded by a matrix material, wherein each of the plurality of metastable heteroepitaxially grown semiconductor alloy predecessor structures has an associated band gap and the matrix material surrounding the metastable heteroepitaxially grown semiconductor alloy predecessor structures has a second band gap;

reducing the associated band gap of each of the plurality of metastable heteroepitaxially grown semiconductor alloy predecessor structures by a structural transformation that creates a newly arising long range ordering, resulting in a plurality quantum dots each having a band gap that is less than the band gap of the matrix material at least partly due to the newly arising long range atomic ordering of the plurality of newly formed semiconductor quantum dots and at least partly due to the different chemical net composition of the plurality of newly formed quantum dots from that of the surrounding matrix.

In one embodiment of the present invention, the reduction in the band gap of the compositionally modulated/structurally transformed quantum dots is mainly due to the atomic ordering.

In another embodiment of the present invention, the metastable heteroepitaxially grown semiconductor alloy predecessor structure is provided by a gas phase epitaxy technique such as molecular beam epitaxy and metal-organic vapor phase epitaxy.

In yet another aspect of the present invention, the metastable heteroepitaxially grown semiconductor alloy predecessor structure consists mainly of ordinarily strained semiconductor quantum dots.

In a further aspect of the present invention, the metastable heteroepitaxially grown semiconductor alloy predecessor structure consists mainly of a short-period superlattice containing ordinarily strained quasi-2D semiconductor platelets with a smaller bandgap than the surrounding matrix.

In another aspect of the methods of the present invention, controlling the formation rate of structurally stable, compositionally modulated/structurally transformed quantum dots at a given thermal treatment temperature is performed by incorporating dopants and/or other point defects into the structurally metastable semiconductor alloy predecessor structure.

Yet another aspect of the present invention is embodied by a semiconductor device made by the method of claim 1 where the operation temperature of the device is at a temperature for which the quantum dots are thermodynamically stable.

The present invention has several benefits and advantages.

One benefit is that the invention does provide a new generic type of semiconductor quantum dot which is characterized by structural stability for many years at room temperature and a reasonable device operation temperature.

Another benefit of the invention is that structural transformations/compositional modulations with varying degree of atomic long-range order, i.e. crystallographic superlattices (also known as Landau-Lifshitz compounds), chemical superlattices, or novel phases can be formed. Those of ordinary skill in the art will recognize that having a choice among degrees of long range order can be useful for a variety of reasons including the width and spacing of the bandgaps of the quantum dots formed.

Still further benefits and advantages of the invention will be apparent to the skilled worker from the discussion that follows.

### BRIEF DESCRIPTION OF DRAWINGS

In the drawings forming a portion of this disclosure:

FIG. 1 is an atomic resolution Z-contrast scanning transmission electron micrograph, [001] plan view, that shows a structurally transformed/compositionally modulated In (As,Sb) quantum dot with a high degree of atomic long-range order in InAs matrix (resulting in a novel phase);

FIG. 2 is an atomic resolution Z-contrast scanning transmission electron micrograph, [001] plan view, that shows a structurally transformed/compositionally modulated In(As,Sb) quantum dot with a low degree of atomic long-range order in InAs matrix (resulting in a chemical superlattice);

FIG. 3 is a high resolution transmission electron micrograph, [001] plan view, that shows a structurally transformed/compositionally modulated (In,Ga)Sb quantum dot with a high degree of atomic long-range order in GaSb matrix (i.e. a novel phase) that remained structurally stable throughout subsequent thermal treatments in vacuum at 300° C. for 2 hours, at 475° C. for 2 hours, and at 500° C. for 2 hours;

FIG. 4 is an atomic resolution Z-contrast scanning transmission electron micrograph, <110> cross section, that shows a structurally transformed/compositionally modulated (In,Ga)Sb quantum dot with a high degree of atomic long-range order in GaSb matrix (resulting in a crystallographic superlattice);

FIG. 5 is a high resolution transmission electron micrograph, [001] plan view, that shows a structurally transformed/compositionally modulated (Cd,Zn)Se quantum dot with a high degree of atomic long-range order in ZnSe matrix (resulting in a crystallographic superlattice);

FIG. 6 is a selected area electron transmission diffraction pattern, [001] plan view, that shows a reciprocal space image of structurally transformed/compositionally modulated (Cd,Zn)Se quantum dot with a high degree of atomic long-range order in ZnSe matrix (resulting in a crystallographic superlattice) that belongs to a quantum dot array of enhanced shape/size and intra-array homogeneity;

FIG. 7 is a high-resolution transmission electron micrograph, <110> cross section, that shows a structurally transformed/compositionally modulated (Cd,Mn,Zn)Se quantum dot with a high degree of atomic long-range order in (Mn,Zn)Se matrix (resulting in a crystallographic superlattice);

FIG. 8a is a low magnification Z-contrast scanning transmission electron micrograph, [001] plan view, that shows structurally metastable ordinarily strained (Cd,Mn,Zn)Se quantum dots in (Mn,Zn)Se matrix which were produced by thermal processing of a metastable semiconductor alloy predecessor structure of a short-period superlattice of quasi-2D CdSe rich platelets in (Mn,Zn)Se matrix at 300° C. for 20 minutes;

FIG. 8b is a medium magnification Z-contrast scanning transmission electron micrograph, [001] plan view, that shows (structurally more stable) structurally transformed/compositionally modulated (Cd,Mn,Zn)Se quantum dots with a low degree of atomic long-range order (resulting in a chemical superlattice) in (Mn,Zn)Se matrix that were produced by a thermal processing of a metastable semiconductor alloy predecessor structure short-period superlattice of quasi-2D CdSe rich platelets in (Mn,Zn)Se matrix after heating at 300° C. for 40 minutes;

FIGS. 9a,b are atomic resolution Z-contrast scanning transmission electron micrographs, <110> cross section, that show the formation of novel type α-Sn quantum dots in Si matrix by means of a thermal treatment below the critical temperature on the basis of the void mediated formation mechanism. Quantum dots with a high degree of atomic long-range order are formed. While FIG. 9a shows voids in Si which are only partially filled with α-Sn, FIG. 9b shows the same voids after a thermal treatment (inside the electron microscope at 300° C. for approximately 3 hours) which resulted in the formation of α-Sn quantum dots in Si matrix;

FIG. 10 is an atomic resolution Z-contrast scanning transmission electron micrograph, [110] cross section, that shows a (Sn,Si) quantum dot in the β-Sn structural prototype surrounded by the Si matrix; and

FIG. 11 is a selected area electron transmission diffraction pattern, [001] plan view, that shows evidence for the existence of atomically ordered SnₓSi_{y} compounds.

### DETAILED DESCRIPTION OF THE INVENTION

Although the present invention is susceptible of embodiment in various forms, there is shown in the drawings and will hereinafter be described a presently preferred embodiment with the understanding that the present disclosure is to be considered an exemplification of the invention and is not intended to limit the invention to the specific embodiments illustrated.

It is to be further understood that the title of this section of the specification, namely, “Detailed Description of the Invention” relates to a requirement of the United States Patent and Trademark Office, and is not intended to, does not imply, nor should be inferred to limit the subject matter disclosed herein or the scope of the invention.

The present invention relates to the formation of a new type of semiconductor quantum dot which is characterized by structural stability for many years at room temperature and a reasonable device operation temperature. Not wishing to be bound by theory, it is believed that the improved long term structural stability is due to thermodynamically driven atomic rearrangements with respect to the random arrangements of the atoms over their respective sublattices in the particular structural prototypes in which ordinarily strained quantum dots exist.

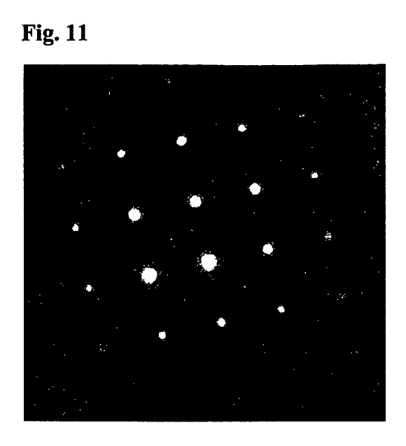

The atomic rearrangements result in structural transformations/compositional modulations with varying degree of atomic long-range order, i.e. crystallographic superlattices (also known as Landau-Lifshitz compounds), chemical superlattices, or novel phases. The formation of quantum dots with superior long term structural stability can be achieved by a combination of heteroepitaxial growth by any method, external lattice mismatch strain and point defect engineering by any means, and specific thermal treatments for certain time durations at a temperature that is below the critical temperature for atomic rearrangements of the specific metastable semiconductor random alloy predecessor structure which formed as a result of the heteroepitaxial growth. Atomic arrangements and rearrangements will be understood by those of ordinary skill in the art, and are further discussed in Möck 2002a & b in press. An atomic rearrangement can be understood to have long range order when the arrangement scatters x-rays or electrons in a manner that produces diffraction spots, see, e.g. FIGS. 6 and 11, which are different from and/or additional to that of a random atomic arrangement of the subject alloy composition or single components thereof.

Although the structural transformation proceeds by a different mechanism for the particular case of the formation of α-Sn quantum dots in Si (Möck 2002b in press, 2002c in press), there is in general a critical temperature above which the novel type quantum dots will be destroyed, i.e. reverse atomic rearrangements to the once which are desired will take place if a thermal treatment is performed above this critical temperature for a certain time period. On the basis of this new type of thermodynamically more stable quantum dot, novel as well as improved opto- and microelectronics devices can be produced that can neither shift nor fail in their device performance over time scales of many years as a result of atomic rearrangements at room temperature or another reasonable device operation temperature.

The well known free energy minimization principle states that at a given temperature, the structure with the lowest free energy is thermodynamically stable, i.e. in other words, the structural ground state of all naturally occurring atomic arrangements at that particular temperature. Structures with larger free energies are either unstable or metastable. Metastable structures are on a fundamental level also unstable but may prevail for a long time if there is a high energy barrier that must be overcome before the ground state can be reached. Both unstable and metastable states can, in other words, be considered as being excited states which will relax into the ground state or lower energy states over a certain time by a certain mechanism. The (Gibbs) free energy (G) of a structure can be calculated from the Gibbs free energy equation G=H−TS+pv, where H is the enthalpy of the structure, T is the thermodynamic temperature, S is the entropy of the structure, p is the pressure on the structure, and V is the volume of the structure. (Those of ordinary skill in the art will note that an analogous discussion can be made on the basis of the Helmholtz free energy equation when an additional energy term that is due to the external lattice mismatch strain is considered.)

The completely random distribution of all cations and all anions over their respective sublattices in the host structure at zero temperature has the largest configurational entropy. At any other temperature, there is, however, a certain concentration of point defects in thermodynamic equilibrium and the configurational entropy is smaller. For cases of binary element or pseudobinary compound semiconductor alloy crystals with adamantine structure in their bulk form, H depends, besides other parameters, on internal strains which are caused by the distribution of the various atoms over the center and corner of the basic tetrahedrons of which the structure can be considered to consist (Zunger et al., Tsao). This is also the case if there are more than three types of atoms in the basic unit cell of the semiconductor.

Considering basic thermodynamics for a random atomic arrangement and an ordered atomic arrangement (designated by a prime sign), a lower Gibbs free energy (G′<G) can be achieved below the critical temperature T_{c} which is defined by the following relation: T_{c}=¹/_{(s-s′)}(H−H′+pV−p′V′). In other words and applied to self-assembled semiconductor quantum dots, a thermodynamics driven atomic rearrangement can transform the random atomic arrangement of an ordinarily strained quantum dot into the ordered atomic arrangement of a quantum dot with a superior long term structural stability as a matter of principle below the such defined critical temperature if the decrease in the product of entropy and the thermodynamic temperature is overcompensated by a reduction in either the enthalpy or the product of the pressure and the volume or both energy terms in the Gibbs equation.

Those of ordinary skill in the art will appreciate from the definition of critical temperature above that the critical temperatures depend on the quotient of the sum of four energy terms and the difference of two entropy terms. Out of these energy terms, the pV term in essence arises from the external lattice mismatch of the ordinarily strained quantum dot with the matrix. The pV term is the most easily amenable to engineering because it can be macroscopically controlled by at least both the growth parameters and the nominal structure parameters. Engineering of this kind is called in this text external lattice mismatch strain engineering.

Simple calculations shows that the external lattice mismatch strain of ordinarily strained quantum dots results in both a significant energy term pV in the Gibbs free energy equation and a significant pressure on the quantum dot as a whole. This energy is somewhere between 0.1 and 1.5 eV per every atom of a typical quantum dot and there is an essentially hydrostatic pressure of the order of magnitude 1 to 10 GPa on a typical quantum dot as a whole (Möck et al. 2002a and 2002b in press, 2002c in press). The release of this excess Gibbs free energy (i.e. stored elastic mismatch strain energy) drives structural transformations in certain temperature ranges which result in quantum dot structures with lower Gibbs free energy and superior structural stability. Such quantum dot structures can be either new crystallographic phases, that may or may not be high pressure phases of the semiconductors in question, crystallographic superlattices (also know as Landau-Lifshitz compounds), or chemical superlattices (also known as periodic compositional modulations that possess the same structural prototype). In a more general sense, on could speak of all of these possible structures as structurally transformed/compositionally modulated semiconductor quantum dots with varying degree of atomic long-range order (partial or complete) that are structurally stable for many years.

In four different quantum dot materials systems, namely (In,Ga)Sb in GaSb (Möck et al. 2001a), In(Sb,As) in InAs (Möck et al., 2001a,b), (Cd,Mn,Zn)Se in (Mn,Zn)Se (Möck et al. 2001a,b,c) and (Cd,Zn)Se in ZnSe (Möck et al. 2002a and 2002b in press), various novel type quantum dots with transformed structures/compositional modulations and lattice mismatch stain reducing orientation relationships exist. In all four cases, the structures can be grown by means of the Stranski-Krastanow mode and its variants (such as using surfactants (Topuria) or stacking of multilayers of quasi-2D CdSe rich platelets and spacer layers). In a fifth quantum dot materials system, namely Sn in Si, the formation of quantum dots by means of both the known phase separation mechanism (Ragan et al., Möck et al. 2002b in press, 2002c in press) and a novel void mediated mechanism (Möck et al. 2002b in press, 2002c in press) have been observed.

While the phase separation mechanism results in ordinarily strained random alloy (Sn,Si) quantum dots, the novel void mediated growth mechanism of quantum dots results in α-Sn quantum dots with superior long term structural stability. The ordinarily strained random alloy (Sn,Si) quantum dots are metastable at room temperature and transform from the diamond structure into the β-Sn prototype by a thermal treatment (Ridder at al.) or over time (Möck et al. 2002b in press). Atomically ordered SnₓSi_{y} compound quantum dots formed by means of atomic ordering from random alloy (Sn,Si) predecessor structures (Möck et al. 2002b in press) can also be produced. The structural transformations are believed to typically be accompanied by morphological transformations because the observed shape of the novel type quantum dots appears to be determined to a first approximation (for very small precipitates) by the anisotropy of the interface energy density (Johnson). Morphological transformations can also proceed in ordinarily strained quantum dots over time as they lead to a reduction of the stored elastic mismatch strain energy (Möck et al. 2002b in press).

In summary, the random alloy In(Sb,As), (In,Ga)Sb, (Cd,Mn,Zn)Se, (Cd,Zn)Se, and (Sn,Si) quantum dots, mentioned above, are all metastable at room temperature and have all been transformed structurally into quantum dots with superior long term structural stability. All these novel type quantum dots are either crystallographic superlattices that possess long-range order in the cation or anion sublattices (also known as Landau-Lifshitz compounds), or short period chemical superlattices, or new phases that may or may not be high pressure phases of the respective semiconductors. Recent reviews on high pressure phases of semiconductors (McMahon and Nelmes, Nelmes et al.) show that alloyed compound semiconductors are unexplored, but many of the pure substance II-VI and III-V compound semiconductors do undergo structural transformations at hydrostatic pressures of the order of magnitude 1 to 10 GPa, i.e. pressures in the same range as those which are typically acting on compressively strained quantum dots.

The observed nano-agglomerates (Möck et al. 2001a,b,c, 2002a and 2002b in press, 2002c in press) constitute a generic group of a novel type of semiconductor quantum dot as these entities fulfill all of the criteria that have to be met for a structure to be considered a quantum dot. Structurally, these quantum dots are either the thermodynamic ground state or over long time scales prevailing states of the respective atomic arrangements at room temperature since our analyses were undertaken after these structures have been stored at ambient air and normal pressure for times ranging form about 18 month to 5 years. As the epitaxial growth methods, nominal structure types, and materials systems were different in the samples that were analyzed and since atomic ordering was observed in both the cation and the anion sublattices of the sphalerite structure (Möck et al., 2001a), thermodynamically driven atomic rearrangements appear to be the destiny of epitaxially grown random alloy ordinarily strained semiconductor quantum dots. Some ordinarily strained semiconductor quantum dots may, however, be metastable for longer times than others.

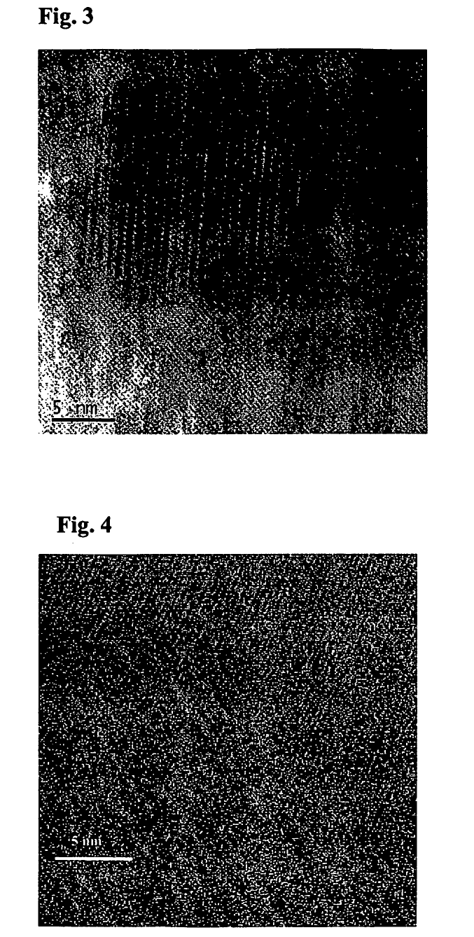

Both the structural instability of ordinarily strained semiconductor quantum dots, which were originally present in two of these structures (Norman et al., Möck et al. 1999) and atomic rearrangements at room temperature (i.e. their short term structural metastability at this temperature) were observed along with the observation of a novel type of semiconductor quantum dot that is characterized by crystallographic/chemical superlattices or novel phases (i.e. atomic rearrangements with respect to the structure of ordinarily strained quantum dots) and/or an improved structural stability at room temperature and a reasonable device operation temperature (P. Möck et al. 2001a,b,c, 2002a, 2002b in press, 2002c in press). (Room temperature is typically about 300 K, give or take several degrees, and a reasonable device operation temperature can typically range from about 1 K up to the melting temperature of the quantum dot or its surrounding matrix or other important components in the device, but is more preferably, about 250-350 K, and most preferably being room temperature) Given the observation of high temperature structural stability of novel type (In,Ga)Sb quantum dots against atomic disordering at temperatures of up to 500° C., see FIG. 3, i.e. above the epitaxial growth temperature and by far higher then a reasonable device operation temperature, we consider the novel type of semiconductor quantum dot we discovered as the most suitable building blocks for novel and improved opto- and micro-electronic devices.

This invention is based on the properties just discussed (Möck et al., 2001a, 2002a, 2002b in press) and can be easily understood from basic thermodynamics as applied to heteroepitaxially grown semiconductor alloys. A lower Gibbs free energy (G′<G) can for an epitaxially grown metastable semiconductor alloy predecessor structure with a random distribution of the atoms over their respective sublattices be achieved below the critical temperature for atomic rearrangements (T_{c}<¹/_{(s-s′)}{H−H′+pV−pV′}, V=V′ in a first approximation) where the decrease in the product of entropy and the thermodynamic temperature is overcompensated by either a reduction in the product of the pressure and the volume (i.e. elastic lattice mismatch strain energy), or a reduction in the enthalpy, or both forms of energies in the Gibbs equation.

When a particular, external lattice mismatch strain and point defect engineered, heteroepitaxially grown semiconductor random alloy predecessor structure, e.g. a system of ordinarily strained quantum dots or a system containing voids and a content of another atomic species that is above the thermodynamic equilibrium, is kept below its specific critical temperature for atomic rearrangements for a sufficient time, atomic rearrangements within the semiconductor alloy predecessor structure will lead with necessity to structurally transformed/compositionally modulated quantum dots (with varying degrees of atomic long-range order) that are for many years stable at room temperature and a reasonable device operation temperature.

For the special case of ordinarily strained quantum dots that were grown in the Stranski-Krastanow growth mode and its variants, atomic rearrangement that are driven by thermodynamics will create atomic order out of the random distribution of the atoms in ordinarily strained quantum dots and result in the new type of thermodynamically more stable quantum dots with transformed atomic structure. For the same external lattice mismatch strain and point defect population, this key structural transformation will be the faster the higher the temperature is. It can be beneficial to keep the metastable structure at a temperature at or below the critical temperature of atomic rearrangements while staying near the critical temperature.

For the special case of quantum dot predecessor structures that were grown by growth temperature and growth rate modulated molecular beam epitaxy (Min and Atwater, Ragan et al.), atomic rearrangement that are driven by thermodynamics will also create atomic order out of the random distribution of the atoms in the metastable random alloy predecessor structure, albeit by two different mechanisms, i.e. filling voids or structural transformations. By filling of the voids, pure substance quantum dots will result. Structural transformations, on the other hand, will lead to crystallographic or chemical superlattices or novel phases. In both cases, however, a reduction of the Gibbs free energy will result and novel type semiconductor quantum dots that are thermodynamically more stable will come into being.

In some cases, it may for economic or other technical reasons neither be necessary nor advisable to prolong the thermal treatment until the thermodynamic ground state of the novel type quantum dots is reached. If one creates novel type quantum dot structures that are metastable for many years, devices that have an expected life time that is shorter than this time scale will work as reliably as devices that are based on novel type quantum dots in their thermodynamic ground state. Such constructs while they may be inferior for some purposes, may be acceptable or superior for other purposes. Thus, while a type of quantum dot that is not structurally stable for a time period as long as eighteen months at standard temperature and pressure is not suitable for most applications, there may be some that it is suitable for. Similarly, quantum dots that are stable at standard temperature and pressure for more than 4 years are suitable for more applications than a quantum dot that lasts only eighteen months.

One aspect of the invention is to apply a thermal treatment below the critical temperature of atomic rearrangements to a lattice mismatch and point defect engineered system of a metastable semiconductor random alloy predecessor structure and transform such a system into an energetically lower state which is structurally more stable at room temperature or a reasonable device operation temperature. As the mechanisms of these transformations and their rate are controlled by dopants and other point defects as well as by mechanical stresses, both the point defect and the external lattice mismatch strain engineering efforts determine for a given structurally metastable semiconductor random alloy predecessor structure and temperature the time duration of the thermal treatment below the critical temperature for atomic rearrangements.

The conditions of the thermal treatment can be varied, and may be dependent on the properties of the materials being treated. As discussed above, a suitable temperature should not render the sample useless. Temperatures of 100° C. to 500° C. can be used with a variety of semiconductor compounds. Techniques known to those of ordinary skill in the art for the heating of semiconductors for either laboratory or industrial application can be used.

Similarly, a suitable atmosphere of heating can be at standard atmospheric, or increased or decreased pressure. Generally, the atmosphere that the heating is conducted in should not have undesirable reactions with the sample at the temperatures and/or pressures used. The use of noble gasses such as He, Ne, Ar, Kr, or Xe, will be unreactive with most semiconductor compounds. Similarly, other gasses, including, but not limited to dry nitrogen or carbon dioxide will also be unreactive with most semiconductor compounds. However, under some circumstances, such as combining the doping and heat treatment of samples can have chemical reactions proceeding simultaneously with heating, and make the presence of a reactive gas desirable.

Reduced pressure, such as found in electron microscopes and other equipment, can be advantageous for heating samples by reducing the presence of all reactive species. On the other hand, certain samples, including, but not limited to those containing arsenic, can lose semiconductor material during heating if not subjected to increased pressure. In such circumstances, those of ordinary skill in the art will recognize the use of increased pressure can allow treatments that would not be successful at standard or reduced pressures.

The following example, provided to illuminate the invention for those of ordinary skill in the art, are provided to exemplify, but not limit, the scope of the present invention.

### EXAMPLE 1

### Formation of Structurally Transformed/compositionally Modulated In(As,Sb) Quantum Dots in InAs Matrix

The heteroepitaxial growth proceeds by means of atmospheric pressure metal organic chemical vapor deposition at a susceptor temperature of 480° C. InAs is used as substrate and trimethylindium, arsine, and trimethylantimony are used as precursors. The nominal structures are 300 nm InAs buffer layer, 1-2 monolayers of InSb, and 300 nm InAs capping layer. The deposition rate is 0.5 to 1 monolayer per second. Prior and after the deposition of the pseudomorph InSb layer that rearranges itself into strained 3D nano-islands of In(Sb,As) with a larger InSb content than the surrounding wetting layer (i.e. alloy predecessors of ordinarily strained In(Sb,As) quantum dots), growth pauses of 5 seconds are kept under flowing H₂. The deposition of the capping layer transforms the strained 3D nano-islands of In(Sb,As) into ordinarily strained quantum dots of In(Sb,As) in InAs matrix (Norman et al. 1997, Möck et al. 1999) that comprise a thermodynamically metastable semiconductor random alloy predecessor structure at room temperature (P. Möck et al., 2000a) and a reasonable device operation temperature.

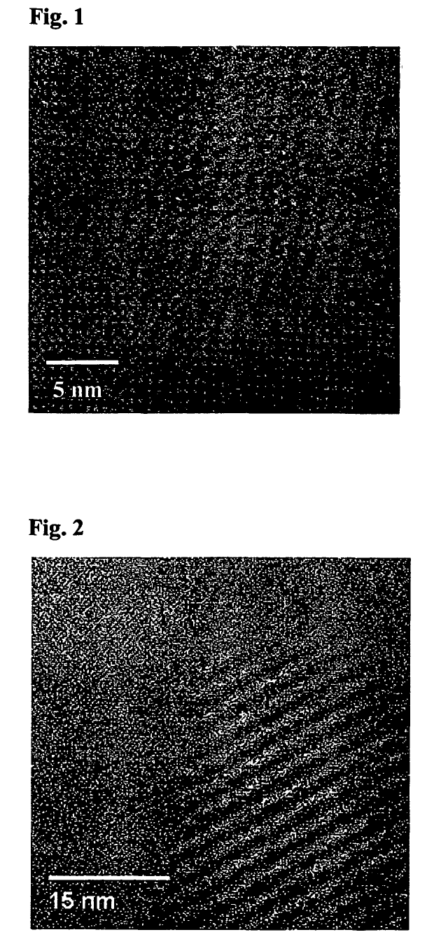

This ordinarily strained quantum dot semiconductor alloy predecessor structure is either kept at room temperature in ambient air of normal pressure for about four years or is subjected to a thermal treatment at another temperature below the critical temperature for atomic rearrangements for this metastable structure for a sufficient time under an ambient gas of a suitable kind and pressure, resulting in the formation of structurally transformed/compositionally modulated In(As,Sb) quantum dots with varying degrees of atomic long-range order in InAs matrix (FIGS. 1 and 2) that have a significantly smaller bandgap than the random semiconductor alloy of the same net chemical composition (Kurtz et al., Zunger at el., Lanks et al.) and luminesce in the first (Möck et al., 2001a) or second atmospheric window.

### EXAMPLE 2

### Formation of Structurally Transformed/compositionally Modulated (In,Ga)Sb Quantum Dots in GaSb Matrix

The heteroepitaxial growth proceeds by means of atmospheric pressure metal organic chemical vapor deposition at a temperature of 480 to 500° C. GaSb substrates or GaSb/GaAs pseudosubstrates are used. The precursors are trimethylindium, trimethylgallium, and trimethylantimony. The deposition rate is 0.5 to 1 monolayer per second. Prior and after the deposition of the pseudomorph InSb layer that rearranges itself into strained 3D nano-islands of (In,Ga)Sb with a larger InSb content than the surrounding wetting layer (i.e. alloy predecessors of ordinarily strained (In,Ga)Sb quantum dots) growth pauses of 2 to 5 seconds are kept under flowing H₂. The deposition of the capping layer transforms the strained 3D nano-islands of (In,Ga)Sb into ordinarily strained quantum dots of (In,Ga)Sb in GaSb matrix (P. Möck et al. 2000, P. Möck et al. 2001d) that comprise a thermodynamically metastable semiconductor random alloy predecessor structure at room temperature (P. Möck et al. 2001a) and a reasonable device operation temperature.

This ordinarily strained quantum dot semiconductor alloy predecessor structure is either kept at room temperature in ambient air of normal pressure for about four years or is subjected to a thermal treatment at another temperature below the critical temperature for atomic rearrangements for this metastable structure for a sufficient time under an ambient gas of a suitable kind and pressure, resulting in the formation of structurally transformed/compositionally modulated (In,Ga)Sb quantum dots with varying degrees of atomic long-range order in GaSb matrix (FIGS. 3 and 4) that have, as predicted by theory (Zunger et al., Lanks et al.), a significantly smaller bandgap than the random semiconductor alloy of the same net chemical composition.

### EXAMPLE 3

### Formation of Structurally Transformed/compositionally Modulated (Cd,Zn)Se Quantum Dots in ZnSe Matrix

The growth method used is molecular beam epitaxy. Elemental sources are used and the heteroepitaxial growth proceeds at 350° C. ZnSe/GaAs pseudo-substrates are used and nominally 100 nm of ZnSe are deposited as a buffer layer. 2.6 nm of CdSe is deposited on the buffer layer which rearranges itself into 3D nano-islands and smaller essentially 2D nano-platelets. Both kinds of CdSe rich entities possess effective 3D quantum confinement properties for excitons (Strassburg et al.). Finally a ZnSe capping layer of 50 nm thickness is grown. The result of the epitaxial growth procedure comprises a thermodynamically metastable semiconductor random alloy predecessor structure at room temperature (P. Möck et al. 2002a) and a reasonable device operation temperature.

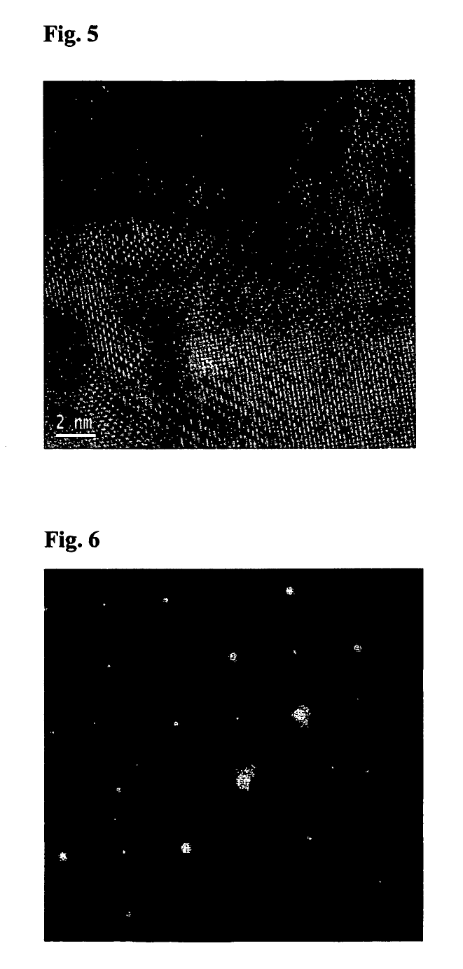

This ordinarily strained quantum dot semiconductor alloy predecessor structure is either kept at room temperature in ambient air of normal pressure for about four years or is subjected to a thermal treatment at another temperature below the critical temperature for atomic rearrangements for this metastable structure for a sufficient time under an ambient gas of a suitable kind and pressure, resulting in the formation of structurally transformed/compositionally modulated (Cd, Zn) Se quantum dots with varying degrees of atomic long-range order in ZnSe matrix (FIG. 5) that have, as predicted by theory (Zunger et al., Lanks et al.), a significantly smaller bandgap than the random semiconductor alloy of the same net chemical composition.

### EXAMPLE 4

### Formation of Structurally Transformed/compositionally Modulated (Cd,Zn)Se Quantum Dots in ZnSe Matrix with Enhanced Shape/size and Intra-array Homogeneity Due to a Surfactant

The growth method used is molecular beam epitaxy. Elemental sources are used and the heteroepitaxial growth proceeds at 350° C. ZnSe/GaAs pseudo-substrates are used and nominally 100 nm of ZnSe are deposited as a buffer layer. On the buffer layer a sub-monolayer of MnSe is deposited by leaving the Mn shutter open for 1 sec, having the Se shutter closed, and having had the Mn and Se fluxes calibrated in a manner that would result in the deposition of 0.1 monolayers of MnSe if there were a concurrent flux of Se. 2.6 nm of CdSe is then deposited on the buffer layer and MnSe surfactant and rearranges itself into 3D nano-islands. The formation of the smaller essentially 2D nano-platelets takes also place, but results in a much smaller number density of these entities due to the influence of the MnSe surfactant. Finally a ZnSe capping layer of 50 nm thickness is grown. The result of the epitaxial growth procedure comprises a thermodynamically metastable semiconductor random alloy predecessor structure at room temperature and a reasonable device operation temperature. Due to the reduction of the number density of essentially 2D nano-platelets, i.e. the influence of the MnSe surfactant, this quantum dot array is characterized by a higher shape/size and intra-array homogeneity (Topuria).

This ordinarily strained quantum dot semiconductor random alloy predecessor structure is either kept at room temperature in ambient air of normal pressure for about four years or is subjected to a thermal treatment at another temperature below the critical temperature for atomic rearrangements for this metastable structure for a sufficient time under an ambient gas of a suitable kind and pressure, resulting in the formation of structurally transformed/compositionally modulated (Cd,Zn)Se quantum dots with varying degrees of atomic long-range order in ZnSe matrix (FIG. 6) that have, as predicted by theory (Zunger et al., Lanks et al.), a significantly smaller bandgap than the random semiconductor alloy of the same net chemical composition.

### EXAMPLE 5

### Formation of Structurally Transformed/compositionally Modulated (Cd,Mn,Zn)Se Quantum Dots in (Mn,Zn)Se Matrix

The growth method used is molecular beam epitaxy. Elemental sources are used and the heteroepitaxial growth proceeds at 350° C. ZnSe/GaAs pseudo-substrates are used and nominally 100 nm of ZnSe are deposited as a buffer layer. A multilayer structure of 8 sequences of 2.8 nm to 3 nm of Zn_{0.9}Mn_{0.1}Se or ZnSe cladding layer and 0.3 to 0.7 monolayer CdSe sheet is then deposited. While the Zn_{0.9}Mn_{0.1}Se or ZnSe cladding layers grow at a deposition rate of 1 monolayer per second, the CdSe sheets grow at a deposition rate of about 0.04 to 0.5 monolayer per second. As the final (9th) cladding layer of the multilayer structure, 2.8 nm to 3 nm of Zn_{0.9}Mn_{0.1}Se or ZnSe is deposited and finally a ZnSe capping layer of 50 nm thickness is grown. The 0.3 to 0.7 monolayer of CdSe sheets rearrange themselves into ordinarily strained quasi-2D platelets that are richer in CdSe than the surrounding matrix (P. Möck et al. 2001b, P. Möck et al. 2001c, Strassburg et al.) and possess effective 3D quantum confinement properties for excitons (Strassburg et al.). The result of the epitaxial growth procedure comprises a thermodynamically metastable semiconductor random alloy predecessor structure at room temperature (P. Möck et al. 2001a) and a reasonable device operation temperature.

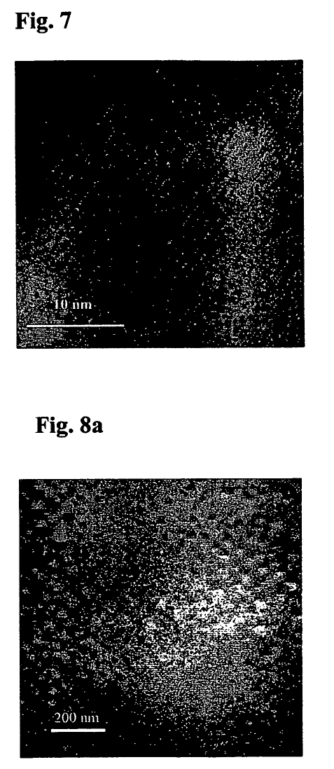

This ordinarily strained quasi-2D platelet semiconductor alloy predecessor structure is either kept at room temperature in ambient air of normal pressure for 18 month or is subjected to a thermal treatment at another temperature below the critical temperature for atomic rearrangements for this metastable structure for a sufficient time under an ambient gas of a suitable kind and pressure, resulting in the formation of structurally transformed/compositionally modulated (Cd,Mn,Zn)Se quantum dots with a high degree of atomic long-range order in (Mn,Zn)Se matrix (FIG. 7) that have, as predicted by theory (Zunger et al. Lanks et al.), a significantly smaller bandgap than the random semiconductor alloy of the same net chemical composition.

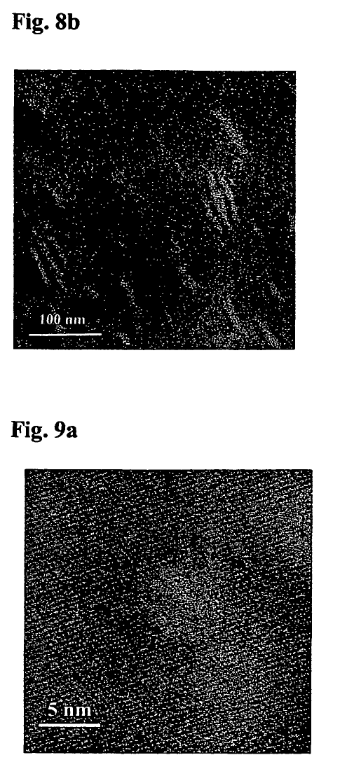

In a first variant of the thermal treatment procedure, such an ordinarily strained quasi-2D platelet (Cd,Mn,Zn)Se semiconductor alloy predecessor structure is first transformed into a metastable ordinarily strained quasi-3D quantum dot structure (FIG. 8a) by a thermal treatment at 300° C. in vacuum for 20 minutes (as this has been achieved before in another II-VI compound semiconductor system, Prechtl et al.). Subsequently, these ordinarily strained quantum dots are subjected to another thermal treatment at a temperature below the critical temperature for atomic rearrangements for this metastable structure for a sufficient time under an ambient gas of a suitable kind and pressure, resulting in the formation of structurally transformed/compositionally modulated (Cd,Mn,Zn)Se quantum dots with a high degree of atomic long-range order in (Mn,Zn)Se matrix that have, as predicted by theory (Zunger et al., Lanks et al.), a significantly smaller bandgap than the random semiconductor alloy of the same net chemical composition.

The vacuum environment used to record the electron micrographs presented in FIGS. 8a and 8b was actually the column of an atomic resolution Z-contrast scanning transmission electron microscope of the type JEOL-JEM 2010F. Consequently the formation of both the ordinarily strained quasi-3D quantum dots (FIG. 8a) and the structurally transformed/compositionally modulated (Cd,Mn,Zn)Se quantum dots with a low degree of atomic long-range order in (Mn,Zn)Se matrix (FIG. 8b) were observed in situ and demonstrate the feasibility of the claimed process for forming semiconductor quantum dots with superior long term structural stability.

In a second variant of the thermal treatment procedure, such an ordinarily strained quasi-2D platelet (Cd,Mn,Zn)Se semiconductor alloy predecessor structure is first transformed into a metastable ordinarily strained quantum dot structure (FIG. 8a) by a thermal treatment at 300° C. in vacuum in the electron microscope for 20 minutes. Subsequently, these ordinarily strained quantum dots are subjected to a second thermal treatment at the same temperature, still in the electron microscope, in vacuum for further 20 minutes, resulting in atomic rearrangements that lead to the formation of structurally transformed/compositionally modulated (Cd,Mn,Zn)Se quantum dots with a low degree of atomic long-range order in (Mn,Zn)Se matrix (FIG. 8b) that possess, as predicted by theory (Zunger et al., Lanks et al.), and like the structure of FIG. 2, a significantly smaller band gap that that of the random semiconductor alloy of the same net chemical composition.

### EXAMPLE 6

### Formation of α-Sn Quantum Dots in Si Matrix by Atomic Rearrangements

The growth method used is growth temperature and growth rate modulated molecular beam epitaxy (Min and Atwater., Ragan et al.) and elemental sources are used. 1 to 2 nm thick (Sn,Si) solid substitutional solutions with a Sn content of 2% to 5% are grown in the diamond structural prototype at 140° C. to 170° C. at a rate of 0.02 nm per second. At the same temperature 4 to 15 nm of Si are grown at a rate of 0.01 to 0.05 nm per second. The temperature is then raised to 550° C. and a capping layer of 100 nm is grown at a rate of 0.05 nm per second. By the time this growth sequence has been completed, the substitutional (Sn,Si) layer has undergone an in-situ thermal treatment at 550° C. for a time period of the order of magnitude 30 minutes. Multilayer structures are grown by repeating this growth sequence several times, resulting in prolonged in-situ thermal treatments of the earlier on deposited substitutional (Sn,Si) layers.

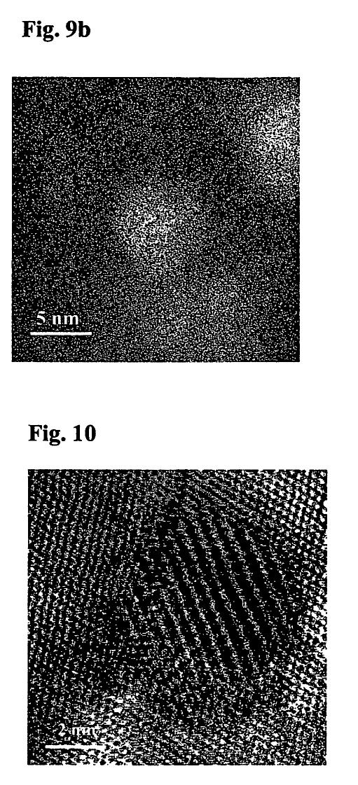

In addition to these in-situ thermal treatments, ex-situ anneals are performed in vacuum at temperatures between 300 and 650° C. for 1 to 5 hours. As a result of the combined thermal treatments, α-Sn quantum dots which possess an improved long term structural stability are formed by filling of the voids in the Si matrix, FIGS. 9a,b, i.e. by thermodynamics driven atomic rearrangements in other words.

The vacuum environment used to record the electron micrographs presented in FIGS. 9a and 9b was actually the column of an atomic resolution Z-contrast scanning transmission electron microscope of the type JEOL-JEM 2010F. Consequently the formation of the α-Sn quantum dots which possess an improved long term structural stability that resulted from filling of the voids in the Si matrix, FIGS. 9a,b, was indeed observed in situ demonstrating the feasibility of the claimed process for forming semiconductor quantum dots with superior long term structural stability.

### EXAMPLE 7

### Formation of Random Alloy (Sn,Si) Quantum Dots with the β-Sn Structural Prototype in Si Matrix by Structural Transformation

The growth method used is growth temperature and growth rate modulated molecular beam epitaxy (Min and Atwater, Ragan et al.) and elemental sources are used. 1 to 2 nm thick (Sn,Si) solid substitutional solutions with a Sn content of 2% to 5% are grown at 140° C. to 170° C. at a rate of 0.02 nm per second. At the same temperature 4 to 15 nm of Si are grown at a rate of 0.01 to 0.05 nm per second. The temperature is then raised to 550° C. and a capping layer of 100 nm is grown at a rate of 0.05 nm per second. By the time this growth sequence has been completed, the substitutional (Sn,Si) layer has undergone an in-situ thermal treatment at 550° C. for a time period of the order of magnitude 30 minutes. Multilayer structures are grown by repeating this growth sequence several times, resulting in prolonged in-situ thermal treatments of the earlier on deposited substitutional (Sn,Si) layers.

In addition to these in-situ thermal treatments, ex-situ anneals are performed at temperatures between 700° C. and 800° C. for 1 to 5 hours. As a result of the combined thermal treatments, random alloy (Sn,Si) quantum dots that formed by means of phase separation in the diamond structure transformed into random alloy (Sn,Si) quantum dots in the β-Sn structural prototype which possess an improved long term structural stability, FIG. 10.

### EXAMPLE 8

### Formation of Atomically Ordered Structurally Transformed SnₓSi_{y} Compound Quantum Dots in Si Matrix

The growth method used is growth temperature and growth rate modulated molecular beam epitaxy (Min and Atwater, Ragan et al.) and elemental sources are used. 1 to 2 nm thick (Sn,Si) solid substitutional solutions with a Sn content of 2% to 5% are grown at 140° C. to 170° C. at a rate of 0.02 nm per second. At the same temperature 4 to 15 nm of Si are grown at a rate of 0.01 to 0.05 nm per second. The temperature is then raised to 550° C. and a capping layer of 100 nm is grown at a rate of 0.05 nm per second. By the time this growth sequence has been completed, the substitutional (Sn,Si) layer has undergone an in-situ thermal treatment at 550° C. for a time period of the order of magnitude 30 minutes. Multilayer structures are grown by repeating this growth sequence several times, resulting in prolonged in-situ thermal treatments of the earlier on deposited substitutional (Sn,Si) layers.

In addition to these in-situ thermal treatments, ex-situ anneals are performed at a temperature of 800° C. for 1 to 5 hours. As a result of the combined thermal treatments, atomically ordered structurally transformed quantum dots consisting of SnₓSi_{y} compound in Si matrix are formed which possess an improved long term structural stability, FIG. 11.

From the foregoing, it will be observed that numerous modifications and variations can be effectuated without departing from the true spirit and scope of the novel concepts of the present invention. It is to be understood that no limitation with respect to the specific embodiment illustrated is intended or should be inferred. The disclosure is intended to cover by the appended claims all such modifications as fall within the scope of the claims. Each of the patents and articles cited herein is incorporated by reference. The use of the article “a” or “an” is intended to include one or more.

Citations

U.S. Patent Documents

| | | |
|---|---|---|
| 4751194 | Jun. 14, 1988 | J. B. Cibert et al. |
| 5073893 | Dec. 17, 1991 | M. Kondou et al. |
| 5354707 | Oct. 11, 1994 | J. D. Chapple-Sokol et al. |
| 5614435 | Mar. 25, 1997 | P. Petroff et al. |
| 5714765 | Feb. 3, 1998 | R. Noetzel et al. |
| 5817538 | Oct. 6, 1998 | K. Mukai |
| 5888885 | Mar. 30, 1999 | Y-H Xie |
| 6033972 | Mar. 7, 2000 | J. R. Ro et al. |
| 6177684 | Jan. 23, 2001 | Y. Sugiyama |
| 6329668 | Dec. 11, 2001 | M. Razeghi |

Foreign Patent Documents

| | | |
|---|---|---|
| 91101136 | Jan. 29, 1991 | EP |
| 91112437 | Jul. 24, 1991 | EP |

Other Citations

D. Bimberg et al., Quantum dot heterostructures, John Wiley and Sons, 1999, Chichester, N.Y., Weinheim, Brisbane, Toronto

G. E. Cirlin et al., Mater. Sci. Engin. B 80 (2001) 108

D. G. Deppe, et al., J. Appl. Phys. 64 (1988) 1838

C. P. Flynn, Point defects and diffusion, Clarendon Press, 1972, Oxford

M. Galluppi et al., Appl. Phys. Lett. 78 (2001) 3121

L. Goldstein et al., J. Appl. Phys. 47 (1985) 1099 L. Jacak at al. Quantum Dots, Springer Verlag, Berlin, Heidelberg, N.Y., 1998.

W. C. Johnson, in: Lectures on the Theory of Phase Transformations, 2nd edition, Ed. H. I. Aaronson, The Minerals, Metals & Materials Society, Warrendale, 2001

P. B. Joyce et al., Phys. Rev. B 58 (1998) R15981

S. R. Kurtz et al., Phys. Rev. B46 (1992) 1909

L. D. Landau and E.M. Lifshitz, Statistical Physics, Pergamon Press, Oxford, 1967, Chapter 14

D. B. Lanks et al., Phys. Rev. Lett. 69 (1992) 3766

N. N. Ledentsov et al., Semiconductors 32 (1998) 343

H-Y. Liu et al., Appl. Phys. Lett. 79 (2001) 2868

Y. Masumoto and T. Takagahara (Editors), Semiconductor Quantum Dots; Physics, Spectroscopy and Applications, Springer Verlag, Berlin, Heidelberg, N.Y., 2002.

M. I. McMahon and R.J. Nelmes, J. Phys. Chem. Solids, 56, 485-490 (1995).

J. C. Mikkelson et al., Phys. Rev. B28 (1983) 7130

K. S. Min and H. A. Atwater, Appl. Phys. Lett. 72 (1998) 1884

A. M. Mintairov et al., Proc. Res. Soc. Symp. Proc. 642 (2001) J3.34.1

P. Möck et al., 1999, Inst. Phys. Conf. Ser. No. 164 (1999) 133

P. Möck et al., 2000, IEE Proc.-Optoelectron. 147 (2000) 209

P. Möck et al., 2001a, Appl. Phys. Lett. 79 (2001) 946

P. Möck et al., 2001b, Mat. Res. Soc. Symp. Vol. 642 (2001) J6.3.1

P. Möck et al., 2001c, J. Electron. Mater. 30 (2001) 748

P. Möck et al., 2001d, Mater. Sci. Engin. B 80 (2001) 112

P. Möck et al., 2002a, Mat. Res. Soc. Symp. Vol. 696 (2002) N8.8.1

P. Möck et al., 2002b in press, Proc. of 47th Annual Meeting of The International Society for Optical Engineering (SPIE), Symposium 4807, “Physical Chemistry of Interfaces and Nanomaterials”, 7-11 Jul., 2002, Seattle, Wash.

P. Möck et al., 2002c in pres, Proc. 2^{nd Intern. Workshop on Quantum Nanostructures & Nanoelectronics, AIST-Tsukuba Research Center, Tsukuba, Japan, Sep.} 9-11, 2002.

R. J. Nelmes et al., J. Phys. Chem. Solids 56 (1995) 539

R. J. Nelmes et al., Phys. Rev. B 47 (1993) 35

A. G. Norman et al. Inst. Phys. Conf. Ser. No. 157 (1997) 353

T. P. Pearsall (editor), Quantum Semiconductor Devices and Technologies, Kluwer Academic Publishers, 2000, Boston, Dordrecht, London

G. Oelgart et al., J. Appl. Phys. 84 (1998) 1588.

G. Prechtl et al., Appl. Phys. Lett. 78 (2001) 2140

R. Ragan et al. Mater. Sci. Engin B 87 (2001) 204

C. Ridder et al. Mater. Sci. Semicond. Proc. 3 (2000) 251

O. B. Shchekin et al. Appl. Phys. Lett. 78 (2001) 3115

A. Sher et al., Phys. Rev. B 36, 4279 (1987)

M. Strassburg et al., Appl. Phys. Lett. 72 (1998) 942

T. Y. Tan et al., Appl. Phys. Lett. 52 (1988) 1240

T. Y. Tan et al., J. Appl. Phys. 61 (1987) 1841

T. Topuria, PhD thesis, University of Illinois at Chicago, in preparation

E. Towe at al., IEEE Journal of elected topics in quantum electronics 6 (2000) 408

J.Y. Tsao, Materials Fundamentals of Molecular Beam Epitaxy, Academic Press, 1994

V. M. Ustinov et al., Semicond. Sci. Technol. 15 (2000) R41

T. Walter et al., Phys. Rev. Lett. 86 (2001) 2381

S-H. Wei and A. Zunger, Appl. Phys. Lett. 56 (1990) 662

S-H. Wei and A. Zunger, Phys. Rev. B 39 (1989) 3279

P. Werner et al., Proc. 6th Int. Symp. on Advanced Physical Fields: Growth of well defined Nanostructures, National Research Institute for Metals, Tsukuba, Japan, Mar. 6-9, 2001, Ed. N. Koguchi

N. D. Zakharov et al., Appl. Phys. Lett. 76 (2000) 2677

A. Zunger at al., in Handbook on Semiconductors, Vol. 3. chapter 19, p. 1399 completely revised edition, 1994, Elsevier Science B.V.

1. A method of forming structurally stable compositionally modulated/structurally transformed semiconductor quantum dots comprising:
providing at least one metastable heteroepitaxially grown semiconductor alloy predecessor structure made of a first semiconductor material embedded in a matrix made of a second semiconductor material using a heteroepitaxial growth method, wherein the metastable heteroepitaxially grown semiconductor alloy predecessor structure has external lattice mismatch strain; and
heating the metastable heteroepitaxially grown semiconductor alloy predecessor structure embedded in the matrix material at a temperature below the critical temperature for structural transformations of the first semiconductor material for a period of time;
wherein the metastable heteroepitaxially grown semiconductor alloy predecessor structure forms a compositionally modulated/structurally transformed semiconductor quantum dot that is more structurally stable than the metastable heteroepitaxially grown semiconductor alloy predecessor structure.

2. The method of claim 1, wherein the compositionally modulated/structurally transformed semiconductor quantum dots are structurally stable at a reasonable device operation temperature.

3. The method of claim 2, wherein the compositionally modulated/structurally transformed semiconductor quantum dots are structurally stable at room temperature.

4. A method according to claim 1 comprising:
providing a plurality of metastable heteroepitaxially grown semiconductor alloy predecessor structures surrounded by a matrix material, wherein each of the plurality of metastable heteroepitaxially grown semiconductor alloy predecessor structures has a first band gap and the matrix material surrounding the metastable heteroepitaxially grown semiconductor alloy predecessor structures has a second band gap;
reducing the associated band gap of each of the plurality of metastable heteroepitaxially grown semiconductor alloy predecessor structures by a structural transformation that creates a newly arising long range atomic ordering, resulting in a plurality of quantum dots each having a band gap that is less than the band gap of the matrix material at least partly due to the newly arising long range atomic ordering of the plurality of newly formed semiconductor quantum dots and at least partly due to the different chemical net composition of the plurality of newly formed quantum dots from that of the surrounding matrix.

5. A method according to claim 4 where the reduction in the band gap of the compositionally modulated quantum/structurally transformed dots is substantially due to long range atomic ordering.

6. A method according to claim 1 where the metastable heteroepitaxially grown semiconductor alloy predecessor structure is provided by a gas phase epitaxy technique such as molecular beam epitaxy and metal-organic vapor phase epitaxy.

7. A method according to claim 1 where the metastable heteroepitaxially grown semiconductor alloy predecessor structure comprises ordinarily strained semiconductor quantum dots.

8. A method according to claim 1 where the metastable heteroepitaxially grown semiconductor alloy predecessor structure comprises a short-period superlattice containing ordinarily strained quasi-2D semiconductor platelets with a smaller bandgap than the surrounding matrix.

9. A method according to claim 1 further comprising:
controlling the formation rate of structurally stable, compositionally modulated/structurally transformed quantum dots at a given thermal treatment temperature by incorporating dopants and/or other point defects into the structurally metastable semiconductor alloy predecessor structure.

10. A semiconductor device made by the method of claim 1 where the operation temperature of the device is at a temperature for which the quantum dots are thermodynamically stable.
